(19) United States
(12) Patent Application Publication
(10) Pub. No.: US 2019/0144283 A1
(43) Pub. Date: May 16, 2019

(54) Apparatus and Method for Large-Scale Production of Graphene

(71) Applicant: CealTech AS, Stavanger (NO)

(72) Inventors: Marius Andreassen Jakobsen, Sandnes (NO); Vitali Datsyuk, Stavanger (NO)

(73) Assignee: CealTech AS, Stavanger (NO)

(21) Appl. No.: 16/098,476

(22) PCT Filed: May 4, 2017
(86) PCT No.: PCT/NO2017/050109

§ 371 Date: Nov. 2, 2018

(30) Foreign Application Priority Data
May 4, 2016 (NO) 20160755

(51) Int. Cl. C01B 32/186; C23C 16/02; C23C 16/26; C23C 16/511

(52) U.S. Cl. CPC C01B 32/186; C23C 16/511; C23C 16/26; C23C 16/0272

(57) ABSTRACT

An apparatus is for continuous production of graphene. The apparatus has a deposition chamber; a means for introducing a carbon-containing gas into the deposition chamber; a rotatable substrate for growing graphene; a plasma generator; a heating element for heating at least a portion of said apparatus; a pump for evacuating said deposition chamber; and a harvesting system for collecting deposited graphene. The rotatable substrate includes an endless, rotatable surface including a material for accepting deposition of a primary carbon layer prior to graphene growth. A method is for the production of graphene by the apparatus as well as graphene obtainable by such a method.

### FIELD

The invention relates to an apparatus for continuous production of graphene, said apparatus comprising: a deposition chamber; a means for introducing a carbon-containing gas into said deposition chamber; a rotatable substrate for growing graphene; a plasma generator; a heating element for heating at least a portion of said apparatus; a pump for at evacuating said deposition chamber; and a harvesting system for collecting graphene. The invention also relates to a method for the production of graphene by means of the apparatus as well as graphene obtainable by means of such a method.

### BACKGROUND

Graphene has excellent properties such as heat dissipation, electrical conductivity, and mechanical strength, and is thereby demanded by many kinds of industries for its application as heat conductor, reinforcing additive, etc. The simplest method to obtain graphene-like material is to oxidize graphite with a strong oxidation agent as disclosed in EP 2639201. However, this oxidation method leads to the production of pristine graphite oxide and/or pristine graphene oxide which does not provide the excellent properties which can be achieved with graphene. For example, graphene oxide is not conductive, and it demonstrates only ⅕ of the mechanical performance compared to graphene.

Another method of graphene production, which is based on a mechanical treatment, is disclosed in European patent application EP 2 275 385 A1. Herein graphene is exfoliated from graphite particles by means of grinding. However, this application discloses that only 4% of the isolated graphene platelets are single-layer graphene. An alternative method for manufacturing graphene is called the CVD (chemical vapor deposition) method for making a film of graphene (disclosed in EP 2817261 A1), but this method procures only small amounts at a time. Thus, to realize the practical applications of graphene, apparatuses and methods for effectively depositing graphene in large or industrial scale quantities and with the desired structures and properties are required.

One method which may be applied for large-scale CVD production of highly ordered graphene materials is to use a movable substrate. A method for using a movable substrate is known in the art for production of aligned carbon nanotubes (CNTs), disclosed in U.S. Pat. No. 8,709,374 B2, wherein take-off reels are used as a key component for alignment of the CNTs. Due to the specificity of the growth of carbon nanotubes, a catalyst deposition is required on the movable substrate which is in contrast to graphene deposition, where no catalyst deposition is needed. An additional disadvantage of the disclosed method for production of aligned CNTs is the high temperature required for synthesis, which is disclosed to be in the range between 600 and 1100° C.

Another movable device is developed in conjunction with a roll-to-roll transfer method for transferring a graphene layer to various kinds of flexible substrates as disclosed in US 2012/0258311. However, this roll-to-roll transfer method is aimed at a transfer of the graphene layers from the deposition substrate, and the moving device is not involved in the production stage of the graphene. Thus, for industrial application of graphene, an apparatus for producing large quantities of graphene with low cost in a short time is highly demanded. Such an apparatus and a method for using said apparatus will be disclosed herein.

### SUMMARY

The invention has for its object to remedy or to reduce at least one of the drawbacks of the prior art, or at least provide a useful alternative to prior art. The object is achieved through features, which are specified in the description below and in the claims that follow. The invention is defined by the independent patent claims, and the dependent claims define advantageous embodiments of the invention.

In a first aspect, the invention relates more particularly to an apparatus for continuous production of graphene, said apparatus comprising:
a deposition chamber;
a means for introducing a carbon-containing gas into said deposition chamber;
a rotatable substrate for growing graphene;
a plasma generator;
a heating element for heating at least a portion of said apparatus;
a pump for at evacuating said deposition chamber; and
a harvesting system for collecting graphene,
   wherein the rotatable substrate includes an endless, rotatable surface comprising a material for accepting deposition of a primary carbon layer prior to graphene growth. The rotatable substrate may have any shape with an endless surface, including but not limited to a belt, a ball, or a disc. The primary carbon layer may comprise e.g. amorphous carbon and carbon allotropes with sp, sp², and sp³ hybridization. The deposition chamber may be, but is not limited to, a reactor for chemical vapor deposition (CVD), plasma enhanced CVD (PE-CVD), hot wall or cold-wall CVD, or any chamber capable of withstanding low pressure and elevated temperature.

The means for introducing a carbon-containing gas may include mass flow controllers (MFCs). The carbon-containing gas may typically be a hydrocarbon gas, optionally premixed with hydrogen, nitrogen, or argon gases, and it may be introduced into the deposition chamber as a source of carbon for deposition of a primary carbon layer and subsequent growth of graphene. Hydrocarbon gas may be chosen from C₁₋₆ hydrocarbons, e.g. methane, ethane, ethylene, propane, propylene, acetylene, and combination thereof. The deposition chamber may be configured for receiving a mixture of gases which may be premixed outside the deposition chamber.

The rotatable substrate may be, for example, a flexible belt comprising metal, metal surface, or metal compounds, wherein said metals or metal compounds may include: metals such as aluminum, bismuth, chromium, cobalt, copper, gallium, germanium, gold, indium, iron, lead, magnesium, mercury, nickel, plutonium, rare earth metal alloys, rhodium, scandium, silver, titanium, tin, uranium, zinc, zirconium; metal oxide compounds such as oxide of aluminum, bismuth, chromium, cobalt, copper, gallium, gold, indium, iron, lead, magnesium, mercury, nickel, plutonium, rare earth metal alloys, rhodium, scandium, silver, titanium, tin, uranium, zinc, zirconium; silicon and silicone oxide; or combination thereof, e.g. metal alloys such as, for example but not limited to nickel or steel-based alloys. The rotatable substrate may be designed with a desired surface area, as a larger surface area may increase the production rate of graphene. The deposition chamber may also contain more than one rotatable substrate. Preferably, the rotatable substrate in the invention may have a surface area of at least 1.0 m², though the apparatus and the method disclosed herein, as well as the graphene product obtainable by means of the method and apparatus, are believed to be novel and inventive with any size of the rotatable substrate. The material for the substrate may be selected depending on the operation conditions, e.g. temperature. For example, copper- or nickel-based alloys may tolerate higher temperature than pure steel. An example of a nickel-based alloy with advantageous properties for use as a rotatable substrate may be Inconel, which has good mechanical resistance even at high temperatures, whereby said rotatable substrate will not deform inside the deposition chamber.

The rotatable substrate may be able to move along its length with a translational velocity which is suitable for removing impurities from the substrate surface, for deposition of the primary carbon layer, and for the growth of graphene. The velocity of the substrate may be controlled by e.g. drive axles. The optimal velocity of the substrate may be decided based on the purification, deposition, growth, and removal capacity of the respective systems, but generally said velocity is decided based on the growth rate of the graphene onto the substrate. Finding the optimal velocity of the substrate may be easily determined by a person skilled in the art e.g. through trial and error, observation, and/or empirical tests. It should also be noted that the rotational velocity of the substrate may be different when cleaning the substrate and/or depositing the mentioned primary carbon layer than when growing and harvesting the graphene, as will be discussed more in detail below. The main technical effect of using a rotatable substrate is to achieve continuous production of graphene, whereby larger quantities may be obtained in shorter times (estimated to be more than 500 kg/year).

The plasma generator may e.g. comprise an Evenson cavity and a radio frequency (RF) power supply to create a RF plasma, which is a microwave plasma in the ultra-high frequency (UHF) portion of the RF spectrum. Typically, the exciting frequency may be in the order of 2450 MHz. The plasma generator may supply microwaves to the vapor, whereby said gas may be converted into a plasma. The effect of the plasma may be to create free radicals, which may be beneficial for etching and removing impurities from the substrate surface, depositing a primary carbon layer from the carbon-containing gas, and growing graphene from the carbon-containing gas. Specific materials for accepting deposition of the primary carbon layer may be beneficially coupled with specific gas species, e.g. combination of cyano radicals for etching a substrate surface to provide a clean surface ready for deposition. The plasma generator may create a plasma at specific regions of the deposition chamber, typically near the surface of the rotatable substrate. A region in the deposition chamber where plasma is created may be referred to as a reaction zone. The apparatus may be constructed such that a portion of the surface of the rotatable substrate will be in the reaction zone. Rotation of the rotatable substrate will thus continuously change the portion of the surface of said rotatable substrate which is in the reaction zone, i.e. change the portion of said surface whereupon graphene growth will occur. Preferably, the portion of the substrate which is in the reaction zone may be substantially flat.

The heating element may be designed to heat all or a portion of the apparatus. For example, it may be designed to heat the surface, or a volume near said surface, of the rotatable substrate whereupon the graphene growth may occur, i.e. the reaction zone. In this way, the temperature at the growth area may be controlled better and kept stable. Additional heating elements may be included if thought appropriate. The reaction temperature in operation may typically be between 0 and 700° C., and preferably below 500° C.

The pump may be any available pump suitable for evacuating the deposition chamber down to sufficiently low pressure. The pressure in the deposition chamber may typically be between 1 and 1000 mTorr, and preferably 250 to 750 mTorr, during operation of the apparatus. Reduced pressure in the deposition chamber may be beneficial for reducing the temperature and thus the energy consumption, and for increasing the plasma generation in order to remove impurities from the rotatable substrate surface, to activate the surface for deposition of a primary carbon layer, followed by growth of graphene.

In embodiments of the invention, the apparatus may comprise a Raman spectroscopy system in conjunction with the deposition chamber for in situ monitoring the graphene growth onto the rotatable substrate, for example growth rate and quality. The Raman spectroscopy systems may typically be focusing on the reaction zone.

The harvesting system may be able to remove the graphene from the surface of the rotatable substrate, thus said harvesting system may be associated with said surface of said rotatable substrate. In this way, the graphene may continuously be removed from the surface of the rotatable substrate, whereby the growth process of said graphene may restart on the primary carbon layer, which is not removed by the harvesting system and may thus be used again as a source to grow graphene onto the rotatable substrate. The surface of the harvesting system, which may be in contact with the surface of the rotatable substrate, may e.g. have brush-like profiles and/or knife-like profiles, whereby the grown graphene may easily be brushed/scraped off said surface of said rotatable substrate. Alternatively, the surface of the harvesting system may have an adhesive layer whereupon the graphene may stick. If the harvesting system has an adhesive layer, said harvesting system may also comprise means for removing the graphene from the harvesting system surface into a collection chamber. The harvesting system may also be equipped with a funnel that may deliver a liquid between the contacting surfaces of the harvesting system and the rotatable substrate in order to remove graphene directly into a liquid medium. Other possibilities for removal of the graphene from the rotatable substrate may be using a magnetic field and/or electrostatic charge applied to contacting surface of the harvesting system, for example by the harvesting system being charged. Optionally, the harvesting system may itself be rotatable, preferably in the direction opposite to the rotatable substrate. The harvesting system may further comprise a mechanism for removing graphene from both surfaces of the rotatable substrate as graphene may grow on both surfaces. For example, graphene grown on the inner surface of the rotatable substrate may be removed via axles or rollers of an auxiliary rotatable substrate

In one embodiment, the apparatus may contain a collecting chamber for the collected graphene, and said collecting chamber may optionally be filled with liquid media. The liquid media in the collection chamber may be e.g. water or any other solvent, or it may be a reaction media which may provide e.g. in situ doping of graphene according to further graphene applications. For example, graphene collection in a collecting chamber filled with ethylene diamine may lead to in situ doping of the graphene surface with amine functional groups. Amino-functional graphene may work as crosslinking agent in bismaleimide (BMI) based thermoset resins, or create cross-linked structures based on graphene, e.g. aerogels. Due to possible differences in quality or properties of graphene grown on the two surfaces of the rotatable substrate, graphene harvested from the inner surface of said rotatable substrate may be collected in a different collecting chamber than the graphene harvested from the outer surface of said rotatable substrate.

In a second aspect, the invention relates to a method for continuous production of graphene by means of an apparatus according to the first aspect of the invention, said method comprising:
providing a clean surface of the rotatable substrate;
continuously growing graphene on said rotatable substrate using plasma-enhanced chemical vapor deposition by addition of the carbon-containing gas to the deposition chamber;
continuously harvesting of the graphene grown on said rotatable substrate by the harvesting system; and
collecting the graphene removed by the harvesting system,
   wherein prior to graphene growth, the method further comprises the step of depositing a primary carbon layer from said carbon-containing gas onto said clean surface of said rotatable substrate by plasma-enhanced chemical vapor deposition.

The clean surface of the rotatable substrate may be provided by cleaning the surface of said rotatable substrate by means of plasma etching prior to deposition of the primary carbon layer, for example by creating a plasma, typically an oxygen plasma, with the plasma generator. The plasma may create free radicals that may react with impurities on the surface of the rotatable substrate. In embodiments of the invention, cleaning of the surface of the rotatable substrate may be conducted when the apparatus is turned on for the first time or after a down time, e.g. due to maintenance, where after said surface of said rotatable substrate will remain clean during subsequent production. The conditions within the deposition chamber for cleaning of the surface of the rotatable substrate may be chosen as appropriate, but typically said conditions, i.e. temperature and pressure, may be substantially the same as during subsequent deposition of the primary carbon layer and growth of graphene. If the clean surface is provided by means of plasma etching, the cleaning period required to provide said clean surface may typically last between 0.5 and 20 min. If oxygen plasma is used for cleaning, said oxygen plasma is flushed out after the cleaning step.

When a clean surface has been provided, hydrogen may be added to the deposition chamber and a hydrogen plasma may be generated before addition of the carbon-containing gas. Upon addition of the carbon-containing gas, a primary carbon layer is deposited onto the surface of the rotatable substrate from the carbon-containing gas, said primary carbon layer comprising mainly, but not necessarily only, carbon allotropes with sp² hybridization. The primary carbon layer may have a thickness varying down to only a few carbon atoms. The primary carbon layer may be relatively unstructured at the atomic level and thus have a high density of locations with a high free energy where nucleation and growth of graphene may begin. Due to the chemistry of the surface, the graphene formed from the primary carbon surface may be created with some structural defects. At the edges of the graphene particles and in places where defects are localized, energy density is higher, which makes possible to start carbon deposition substantially perpendicular to the active carbon surface, thereby forming 3D structure graphene particles. Such three-dimensional graphene structures may be forming just in minutes, at the time when the surface of the rotatable substrate is within the plasma.

The primary carbon layer provides a chemical surface environment which is suitable for rapid growth of graphene, where said graphene may grow in a random orientation with angles between the plane of the graphene sheets and the surface of the rotatable substrate, alternatively the plane of the tangent of the rotatable substrate in case the substrate is curved in within the reaction zone, varying from 0 to 180°, where 0 and 180° define the plane of the substrate or the plane of the tangent. The production volume resulting from this growth behavior of graphene may be several thousand times larger compared to prior art methods for growing single-layer graphene sheets, where graphene layers are deposited in parallel to the substrate (as in CVD and combustion CVD).

Continuous production of graphene may be achieved by virtue of the rotatable substrate and the harvesting system. After graphene growth on the surface of the portion of the rotatable substrate which is in the reaction zone, said portion will move out of said reaction zone and towards the harvesting system, the harvesting system being located downstream of said reacting zone. The harvesting system will remove the graphene from the portion of the surface of the rotatable substrate which is in contact with said harvesting system, while the primary carbon layer will remain on said portion of said surface of said rotatable substrate. The portion of the surface of the rotatable substrate will thereafter continue its movement into the reaction zone, wherein the process will start over. The harvesting system may typically deliver the harvested graphene to a collection chamber. Depending on the graphene applications, graphene may be collected in powdered form, in wetted form, as a graphene dispersion in a suitable liquid, or in the form of graphene strips adhered to suitable surfaces.

In a third aspect, the invention relates to the graphene obtainable by means of the method according to the second aspect of the invention. Unlike more conventional technology for graphene production, the graphene sheets in the present invention do not grow in parallel to the substrate as graphene film or platelets but at an angle varying from 0 to 180 degrees between the plane of the graphene and the substrate, as illustrated in FIG. 1. Thus, graphene grown within the apparatus disclosed herein comprises a distinctive overall structure of the graphene network which we refer to as 3D graphene. The resulting structures may be collected and used as 3D graphene structures, or they may be disassembled and used as regular graphene sheets. In embodiments of the invention, the overall structure of the graphene grown on a specific surface material may be influenced by the chemical properties of said surface material. Thus, the quality of the 3D graphene product may be partly influenced by selection of an appropriate surface material.

### BRIEF DESCRIPTION OF THE DRAWINGS

In the following is described examples of preferred embodiments illustrated in the accompanying drawings, wherein:

FIG. 1 shows in side view (a) and perspective view (b) a schematic illustration of graphene which is grown in the apparatus with the method according to the invention;

FIG. 2 shows a schematic, cross-sectional view of an embodiment of the apparatus for continuous production of graphene according to the invention;

FIG. 3 shows a schematic, cross-sectional view of another embodiment of the apparatus for continuous production of graphene in according to the invention; and

FIG. 4 shows a schematic, cross-sectional view of yet another embodiment of the apparatus for continuous production of graphene according to the invention.

### DETAILED DESCRIPTION OF THE DRAWINGS

Better understanding of many aspects of the invention may be achieved with reference to the enclosed figures depicting different embodiments of apparatuses according to the invention. The components in the figures are not necessarily drawn to scale, as the emphasis is placed on clearly illustrating the principles of the present apparatus and method. In the figures, like reference numerals designate like or similar elements throughout the figures.

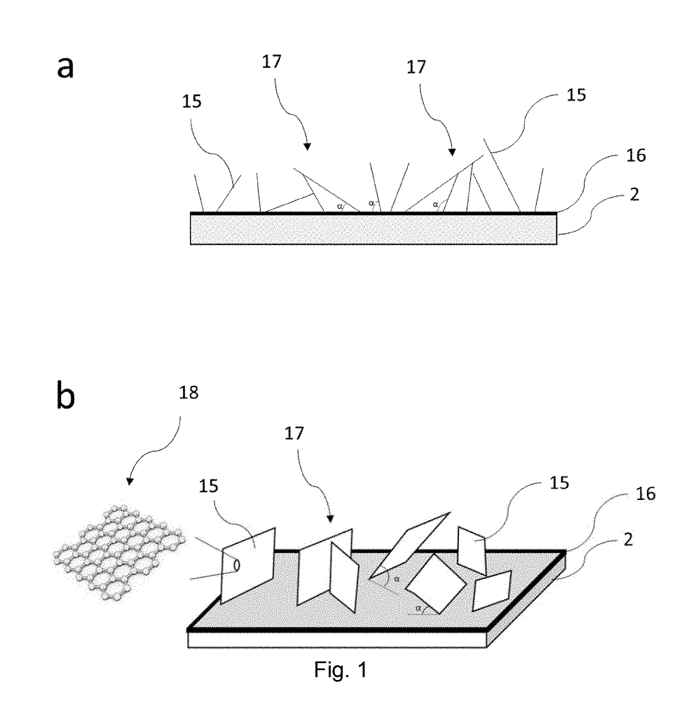

FIG. 1 illustrates how the graphene sheets 15 grow from the primary carbon layer 16 deposited on the surface of the rotatable substrate 2, shown in side view in FIG. 1a and in perspective view in FIG. 1b. The graphene sheets 15 are randomly oriented on the surface of the rotatable substrate 2 with the angle α between the plane of a graphene sheet 15 and the plane of the rotatable substrate 2 varying from 0 to 180°, resulting in the formation of an overall 3-dimensional structure 17 of individual graphene sheets 15. This overall structure 17 is referred to as 3D graphene herein. A magnification view of the atomic structure 18 of the graphene sheets 15 is shown in FIG. 1b.

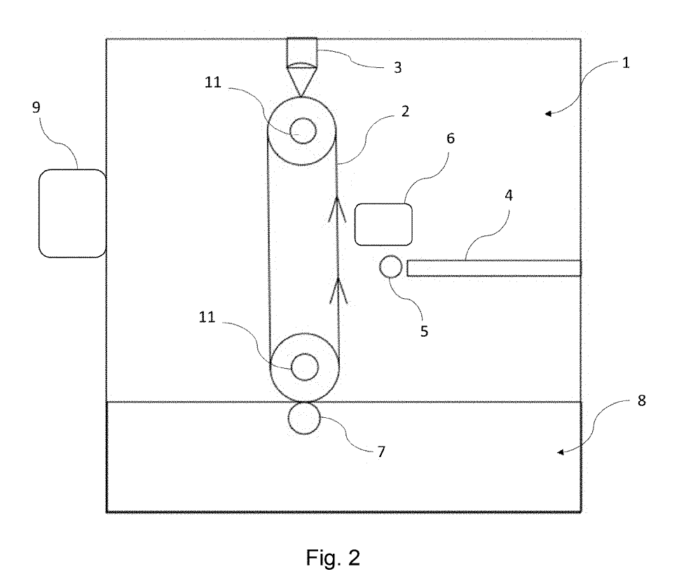

FIG. 2 shows an apparatus for continuous production of graphene sheets. The apparatus comprises a deposition chamber 1, rotatable substrate 2, here shown in the form of a rotatable belt, for deposition of a primary carbon layer and subsequent growth of graphene, drive axles 11 to rotate the rotatable belt 2, a plasma generator 5, e.g. comprising an Evenson cavity and a power supply, a pump 9 as graphene production is carried out at sub-ambient pressure, a gas distribution system 4 controlled by mass flow controller, and a heating element 6 near the beginning of the reaction zone in order to keep the temperature stable and constant. The apparatus further comprises a harts vesting system 7 for removing graphene from the rotatable belt 2, and a collecting chamber 8 to collect the produced graphene. In the shown embodiment, the apparatus also comprises a Raman spectroscopy system 3 focusing on the surface of the rotatable belt 2 after/downstream of the reaction zone.

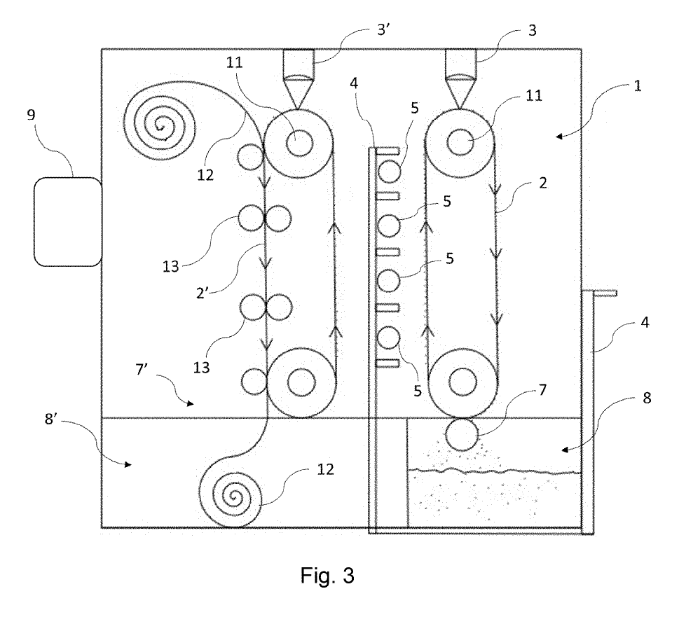

FIG. 3 shows another embodiment of the apparatus according to the invention, wherein the deposition chamber 1 comprises additional elements, for example two rotatable belts 2, 2′ with two

Raman spectroscopy system 3, 3′, a large gas distribution system 4, and several plasma generators 5 for generating a large reaction zone. The heating elements are not shown in this figure. One rotatable belt 2 is associated with a harvesting system 7 as in FIG. 1, while the other rotatable belt 2′ is associated with a harvesting system 7′ comprising a film 12, e.g. a polymer film, whereupon graphene can be transferred. Auxiliary rotation rollers 13 keep the film 12 in contact with the surface of the rotatable belt 2, and said film 12 is then transferred to a different collection chamber 8′.

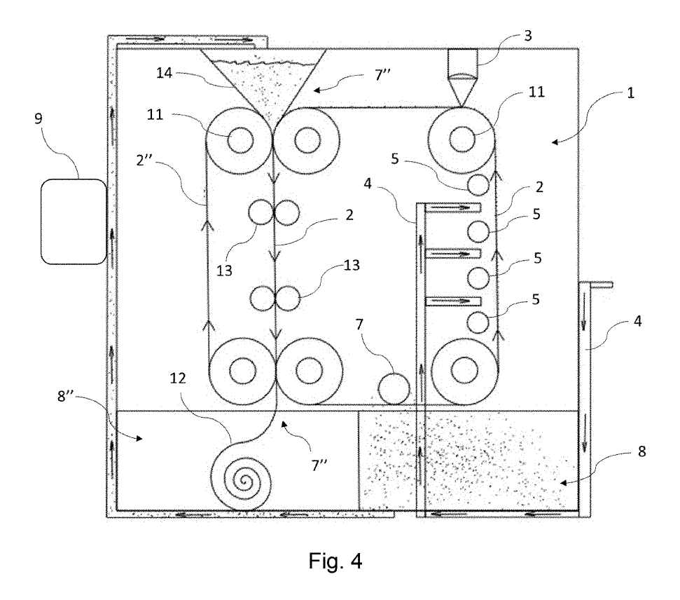

FIG. 4 shows another embodiment of the apparatus according to the invention, wherein graphene is harvested from both sides of the rotatable belt 2 with two different harvesting systems 7, 7″. The first harvesting system 7 transfers the graphene from the inner surface of the rotatable belt 2 to a collecting chamber 8, from where the graphene may be further transferred to a funnel 14.

The funnel 14 may function as a mixing chamber wherein graphene may be mixed with other materials, for example solid or liquid polymers. The second harvesting system 7″ then transfers the contents of the funnel 14 to between the outer surface of the rotatable belt 2 and an auxiliary rotatable belt 2″. Rotation rollers 13 keeps the surfaces of the rotatable belts 2, 2″ in close contact, whereby graphene growing on the outer surface of the rotatable belt 2 is also harvested by the harvesting system 7″. Finally, the graphene is collected in a collecting chamber 8″, for example as a graphene-reinforced polymer film 12.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. Use of the verb “comprise” and its conjugations does not exclude the presence of elements or steps other than those stated in a claim. The article “a” or “an” preceding an element does not exclude the presence of a plurality of such elements.

The mere fact that certain measures are recited in mutually different dependent claims does not indicate that a combination of these measures cannot be used to advantage.

1-26. (canceled)

27. An apparatus for continuous production of graphene, said apparatus comprising:
a deposition chamber;
a means for introducing a carbon-containing gas into the deposition chamber;
a rotatable substrate for growing graphene;
a plasma generator;
a heating element for heating at least a portion of said apparatus;
a pump for evacuating said deposition chamber; and
a harvesting system for collecting graphene,
wherein the rotatable substrate includes an endless, rotatable surface comprising a material for accepting deposition of a primary carbon layer prior to graphene growth.

28. The apparatus according to claim 27, wherein the material for deposition of the primary carbon layer comprises a surface of metal or metal alloys

29. The apparatus according to claim 27, wherein the harvesting system is associated with a part of the surface of the rotatable substrate for removal of the deposited graphene from said surface of said rotatable substrate.

30. The apparatus according to claim 27, wherein the surface of the harvesting system comprises a knife, a brush, an adhesive, a magnetic field, or electric charges for removal of the deposited graphene from the surface of the rotatable substrate.

31. The apparatus according to claim 27, wherein the surface area of the rotatable substrate for deposition of graphene is at least 1.0 m².

32. The apparatus according to claim 27, wherein the plasma generator is a microwave radio frequency generator for generating a plasma through low-pressure reactant gas discharge.

33. A method for continuous production of graphene by means of an apparatus, said method comprising:
providing a clean surface of the rotatable substrate;
continuously growing graphene on said rotatable substrate using plasma-enhanced chemical vapor deposition by addition of the carbon-containing gas to the deposition chamber;
continuously harvesting of the graphene grown on said rotatable substrate by the harvesting system; and
collecting the graphene removed by the harvesting system,
wherein prior to graphene growth, the method further comprises the step of depositing a primary carbon layer from said carbon-containing gas onto said clean surface of said rotatable substrate by plasma-enhanced chemical vapor deposition.

34. The method according to claim 33, wherein the clean surface of the rotatable substrate is provided by cleaning the surface of said rotatable substrate by plasma etching prior to deposition of the primary carbon layer.

35. The method according to claim 33, wherein the carbon-containing gas comprises hydrocarbon gas selected from the group of methane, ethane, ethylene, propane, propylene, acetylene, and combinations thereof.

36. The method according to claim 33, wherein the carbon-containing gas additionally comprises gas selected from the group of hydrogen, oxygen, nitrogen, argon, helium, and combinations of thereof.

37. The method according to claim 33, wherein the continuous production of graphene is performed at a pressure within a range of 1 to 1000 mTorr.

38. The method according to claim 33, wherein the continuous production of graphene is performed at a temperature within a range of 0 to 700° C.

39. The method according to claim 33, wherein graphene is collected as dry powder, as wetted graphene, as graphene-reinforced polymer, or as aligned film.

40. Graphene obtainable by means of the method according to claim 33.

41. The graphene according to claim 40, wherein said graphene has a distinctive 3D structure due to the growth of said graphene sheets in random orientation on the surface of the rotatable substrate at angles from 0 to 180° between the plane of the individual sheets of said graphene and the plane of said surface of said rotatable substrate.
